(19) United States
(12) Patent Application Publication
(10) Pub. No.: US 2015/0228787 A1
(43) Pub. Date: Aug. 13, 2015

(54) SEMICONDUCTOR DEVICE AND MANUFACTURING METHOD THEREOF

(71) Applicant: KABUSHIKI KAISHA TOSHIBA, Tokyo (JP)

(72) Inventor: Masakazu GOTO, Yokohama-Shi (JP)

(73) Assignee: KABUSHIKI KAISHA TOSHIBA, Tokyo (JP)

(21) Appl. No.: 14/288,074

(22) Filed: May 27, 2014

Related U.S. Application Data
(60) Provisional application No. 61/939,106, filed on Feb. 12, 2014.

(51) Int. Cl. H01L 29/78; H01L 21/28; H01L 29/49

(52) U.S. Cl. CPC H01L 29/7845; H01L 29/4966; H01L 29/4916; H01L 21/28035; H01L 21/28088

(57) ABSTRACT

A semiconductor device according to an embodiment includes a semiconductor layer. A first conductivity-type source layer is provided in the semiconductor layer. A second conductivity-type drain layer is provided in the semiconductor layer. A gate dielectric film is provided on the semiconductor layer between the source layer and the drain layer. A gate electrode includes a first gate part partially provided on the gate dielectric film on a side of the source layer and a second gate part partially provided on the gate dielectric film on a side of the drain layer. A length of crystal grains of the first gate part in a channel length direction is longer than that of crystal grains of the second gate part in the channel length direction.

### CROSS REFERENCE TO RELATED APPLICATIONS

This application is based upon and claims the benefit of priority from the prior U.S. Provisional Patent Application No. 61/939,106, filed on Feb. 12, 2014, the entire contents of which are incorporated herein by reference.

### FIELD

The embodiments of the present invention relate to a semiconductor device and manufacturing method thereof.

### BACKGROUND

In recent years, a TFET (Tunnel Field-Effect Transistor) that employs a quantum-mechanical effect of electrons has been developed. In the TFET, by applying a voltage to a gate electrode, BTBT (Band To Band Tunneling) is caused between a source and a channel. As a result, the TFET becomes an on-state.

To increase an on-state current of a TFET, it is effective to introduce strain in a substrate. By introducing strain in a substrate, a bandgap of the substrate becomes narrow and effective mass of conductive carrier is reduced. Tunneling efficiency is thus improved, which increases the on-state current.

In a TFET, the on-state current is determined by tunneling efficiency on the side of a source. Meanwhile, an off-state current is determined by tunneling efficiency on the side of a drain. Therefore, if uniform strain is applied to the side of a source and the side of a drain, there is a problem that not only the on-state current but also the off-state current is increased.

### BRIEF DESCRIPTION OF THE DRAWINGS

FIG. 1 is a cross-sectional view showing an example of a configuration of an N-TFET 100 according to a first embodiment;

FIGS. 2A to 7B are cross-sectional views showing an example of a manufacturing method of the TFET 100 according to the first embodiment;

FIG. 8 is a cross-sectional view showing an example of a configuration of a TFET 200 according to a second embodiment;

FIGS. 9A and 9B are cross-sectional views showing an example of a manufacturing method of the TFET 200 according to the second embodiment;

FIG. 10 is a cross-sectional view showing an example of a configuration of a TFET 300 according to a third embodiment; and

FIGS. 11A and 11B are cross-sectional views showing an example of a manufacturing method of the TFET 300 according to the third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor layer on which semiconductor elements are provided is assumed as “an upper direction”. Therefore, the term “upper direction” or “lower direction” occasionally differs from an upper direction or a lower direction based on a gravitational acceleration direction.

A semiconductor device according to an embodiment includes a semiconductor layer. A first conductivity-type source layer is provided in the semiconductor layer. A second conductivity-type drain layer is provided in the semiconductor layer. A gate dielectric film is provided on the semiconductor layer between the source layer and the drain layer. A gate electrode includes a first gate part partially provided on the gate dielectric film on a side of the source layer and a second gate part partially provided on the gate dielectric film on a side of the drain layer. A length of crystal grains of the first gate part in a channel length direction is longer than that of crystal grains of the second gate part in the channel length direction.

### First Embodiment

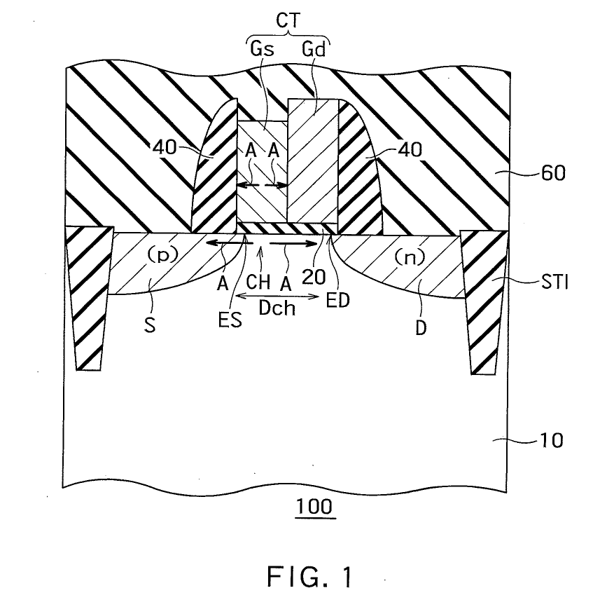

FIG. 1 is a cross-sectional view showing an example of a configuration of an N-TFET 100 according to a first embodiment. The TFET 100 can be used for microprocessors or logic semiconductor integrated circuits such as an ASIC (Application Specific Integrated Circuit).

The TFET 100 includes a semiconductor layer 10, a source layer S, a drain layer D, a gate dielectric film 20, a gate electrode G, a sidewall film 40, and an interlayer dielectric film 60.

The semiconductor layer 10 can be a semiconductor substrate such as a silicon substrate or can be an SOI (Silicon On Insulator) layer on a BOX layer.

The p-type (first conductivity-type) source layer S is formed on a surface region of the semiconductor layer 10. The n-type (second conductivity-type) drain layer D is formed on another surface region of the semiconductor layer 10. The source layer S is formed by implanting a p-type impurity (for example, boron) in the semiconductor layer 10. The drain layer D is formed by implanting an n-type impurity (for example, arsenic or phosphorus) in the semiconductor layer 10. The source layer S is formed on a surface region of the semiconductor layer 10 on the opposite side of the drain layer D across the gate electrode G.

Shallow trench isolation regions STI are provided in the semiconductor layer 10 in order to electrically isolate the TFET 100 from other elements. For example, the shallow trench isolation regions STI are formed of an insulation film such as a silicon oxide film.

The gate dielectric film 20 is provided on the semiconductor layer 10 between the drain layer D and the source layer S. For example, the gate dielectric film 20 is formed of a silicon oxide film, a silicon oxynitride film, or a dielectric film having a higher dielectric constant than that of the silicon oxide film (for example, HfO₂).

The gate electrode G is provided on the gate dielectric film 20. The gate electrode G includes a first gate part Gs on the side of the source layer S and a second gate part Gd on the side of the drain layer D. The first gate part Gs is partially provided on the gate dielectric film 20 on the side of the source layer S. The second gate part Gd is partially provided on the gate dielectric film 20 on the side of the drain layer D.

The first and second gate parts Gs and Gd are both formed of a conductive material such as doped polysilicon or a metal. More specifically, in the first embodiment, the first and second gate parts Gs and Gd are both formed of doped polysilicon. The length of crystal grains of the first gate part Gs in a channel length direction Dch is longer than that of crystal grains of the second gate part Gd in the channel length direction Dch. That is, crystal grains of polysilicon that forms the first gate part Gs are horizontally (laterally) longer than those of polysilicon that forms the second gate part Gd. The height of the first gate part Gs is lower than that of the second gate part Gd. This is because the crystal grains of the first gate part Gs extend in the channel length direction Dch.

Because the crystal grains of the first gate part Gs extend in the channel length direction Dch, the first gate part Gs has a stress to extend in the channel length direction Dch. On the other hand, unlike the first gate part Gs, the second gate part Gd does not have the stress to extend in the channel length direction Dch. Alternatively, the stress of the second gate part Gd is relatively small.

The sidewall film 40 is provided on both side surfaces of the gate electrode G. The sidewall film 40 covers a side surface of the first gate part Gs on the side of the source layer S and a side surface of the second gate part Gd on the side of the drain layer D. For example, the sidewall film 40 is formed of an insulation film such as a silicon oxide film.

The interlayer dielectric film 60 is provided on the gate electrode G and the semiconductor layer 10. For example, the interlayer dielectric film 60 is an insulation film such as a silicon oxide film using TEOS (Tetraethylorthosilicate).

In the first embodiment, as compared to the second gate part Gd, the first gate part Gs has the stress to extend in the channel length direction Dch. Therefore, the first gate part Gs applies a stress to a channel part CH on the side of the source layer S. The second gate part Gd applies a smaller stress to the channel part CH on the side of the drain layer D. As a result, a stress applied to a junction (a source edge) ES between the source layer S and the channel part CH is larger than a stress applied to a junction (a drain edge) ED between the drain layer D and the channel part CH. Arrows A in FIG. 1 indicate the positions and directions of the applied stress.

By setting the stress applied to the source layer S and the source edge ES larger than the stress applied to the drain layer D and the drain edge ED as explained above, tunneling efficiency on the side of the source layer S that determines an on-state current can be improved without increasing tunneling efficiency on the side of the drain layer D that determines an off-state current. Consequently, the TFET 100 can increase the on-state current while suppressing an increase in the off-state current.

According to the first embodiment, the first gate part Gs itself can have a stress and apply the stress to the source edge ES. That is, according to the first embodiment, a stress memorization technique (SMT) is employed to apply a relatively large stress to the source layer S and the source edge ES. In the first embodiment, a stress application film does not need to remain on the gate electrode G for stress application.

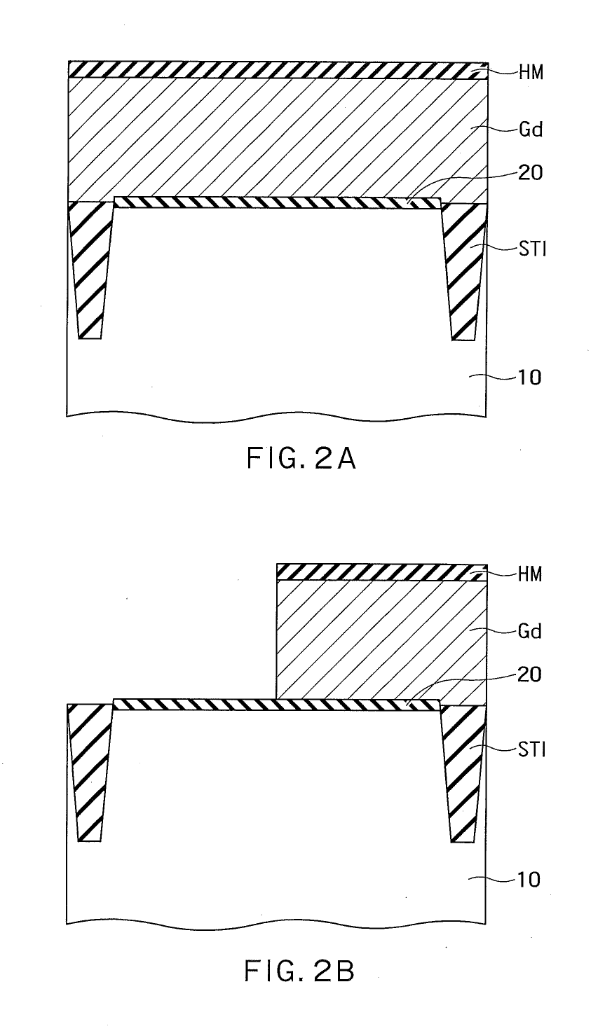

FIGS. 2A to 7B are cross-sectional views showing an example of a manufacturing method of the TFET 100 according to the first embodiment. As shown in FIG. 2A, the shallow trench isolation regions STI are formed first in the semiconductor layer 10. Next, the gate dielectric film 20 is formed on the semiconductor layer 10. As explained above, the gate dielectric film 20 is formed of a silicon oxide film, a silicon oxynitride film, or a dielectric film having a higher dielectric constant than that of the silicon oxide film (for example, HfO₂).

Next, a material for the second gate part Gd is deposited on the material for the gate dielectric film 20 by a CVD (Chemical Vapor Deposition) method. For example, the material for the second gate part Gd is polysilicon. Polysilicon is obtained by film formation of silicon in an atmosphere at a relatively high temperature of about 1000° C. by the CVD method. Next, for example, an n-type impurity (for example, phosphorus) is implanted in the material for the second gate part Gd by an ion implantation method. As a result, the material for the second gate part Gd becomes conductive doped polysilicon. Next, a hard mask HM is deposited on the material for the second gate part Gd by the CVD method. For example, a material for the hard mask HM is an insulation film such as a silicon oxide film. As a result, a configuration shown in FIG. 2A is obtained.

Next, the materials for the hard mask HM and the second gate part Gd are processed by a lithographic technique and an etching technique. At this time, the hard mask HM and the second gate part Gd on a region where the source layer S is formed (hereinafter, “source-layer-S formation region”) and a region where the first gate part Gs is formed (hereinafter, “first-gate-part-Gs formation region”) are removed. As a result, a configuration shown in FIG. 2B is obtained.

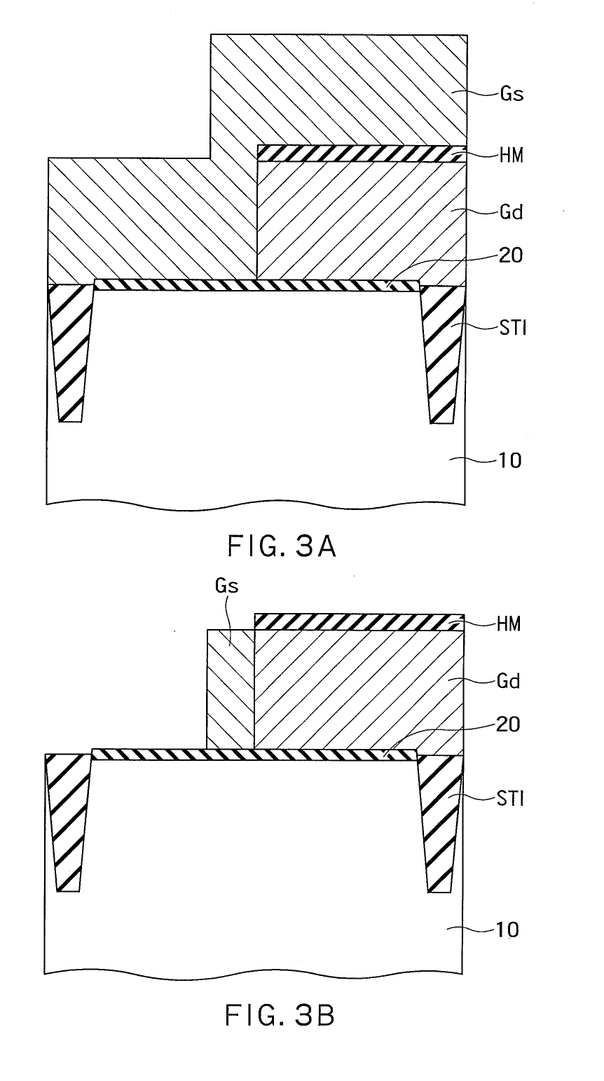

Next, as shown in FIG. 3A, a material for the first gate part Gs is deposited on the source-layer-S formation region and the first-gate-part-Gs formation region by the CVD method. At this time, the material for the first gate part Gs is also deposited on a side surface of the second gate part Gd. The material for the first gate part Gs has a larger thermal expansion coefficient and a smaller Young's modulus than those of the material for the second gate part Gd. More specifically, the material for the first gate part Gs is, for example, amorphous silicon. For example, amorphous silicon is obtained by film formation of silicon in an atmosphere at a relatively low temperature of about 600° C. by the CVD method. Next, for example, an n-type impurity (for example, phosphorus) is implanted in the material for the first gate part Gs by the ion implantation method. As a result, the material for the first gate part Gs becomes conductive doped amorphous silicon.

Next, the material for the first gate part Gs is anisotropically etched by an RIE (Reactive Ion Etching) method. As a result, as shown in FIG. 3B, the first gate part Gs is formed so as to contact the side surface of the material for the second gate part Gd.

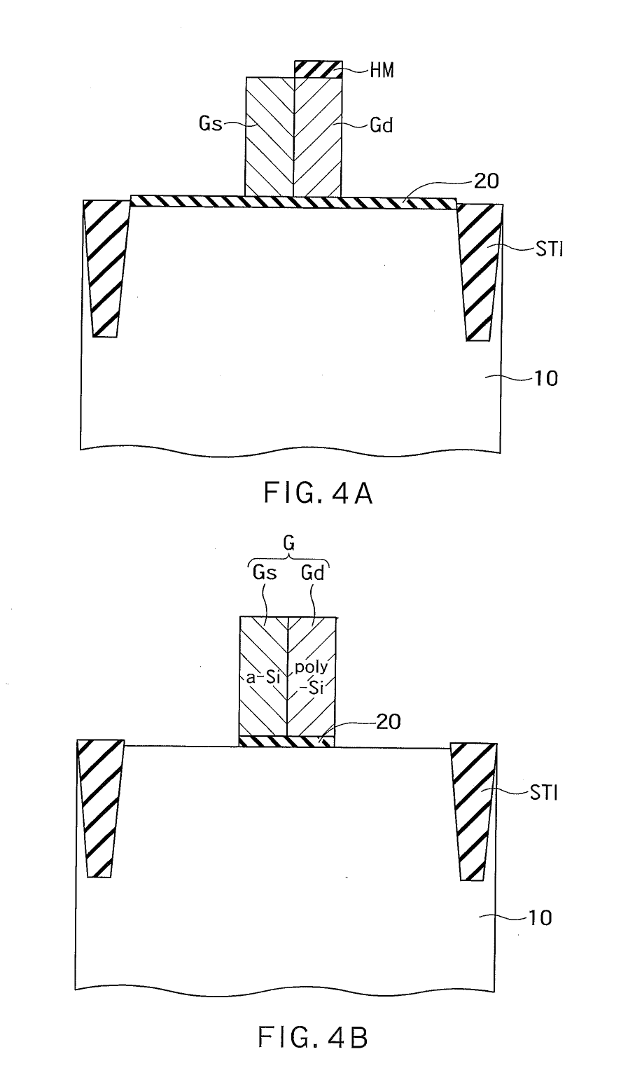

Next, the materials for the hard mask HM and the second gate part Gd are processed by the lithographic technique and the RIE method. As a result, as shown in FIG. 4A, the second gate part Gd is formed.

Next, parts of the hard mask HM and the gate dielectric film 20 are removed by wet etching using a DHF (Dilute Hydrofluoric Acid) or the like. As a result, as shown in FIG. 4B, the first gate part Gs and the second gate part Gd are formed on the gate dielectric film 20. That is, the first gate part Gs and the second gate part Gd that are made of different materials and adjacent to each other are formed on the gate dielectric film 20 as the gate electrode G. In the first embodiment, the gate electrode G that includes the first gate part Gs made of amorphous silicon and the second gate part Gd made of polysilicon is formed on the gate dielectric film 20.

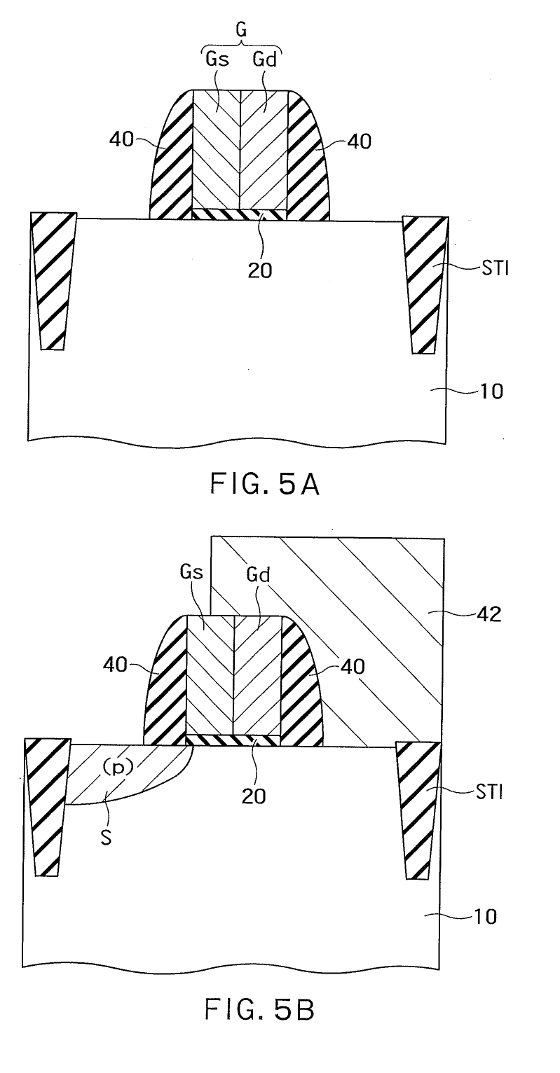

Next, a material for the sidewall film 40 is deposited on top and side surfaces of the gate electrode G and on the semiconductor layer 10 by the CVD method. For example, the material for the sidewall film 40 is an insulation film such as a silicon oxide film. For example, the film thickness of the material of the sidewall film 40 is about 30 nanometers. Next, the material for the sidewall film 40 is anisotropically etched by the RIE method. As a result, as shown in FIG. 5A, the sidewall film 40 remains on both side surfaces of the gate electrode G.

Next, as shown in FIG. 5B, a region where the drain layer D is formed (hereinafter, “drain-layer-D formation region”) is covered by a resist film 42 by the lithographic technique. Next, ions of a p-type impurity (for example, BF₂) are implanted in the source-layer-S formation region (the semiconductor layer 10 on the side of the first gate part Gs of the gate electrode G) by using the resist film 42 as a mask.

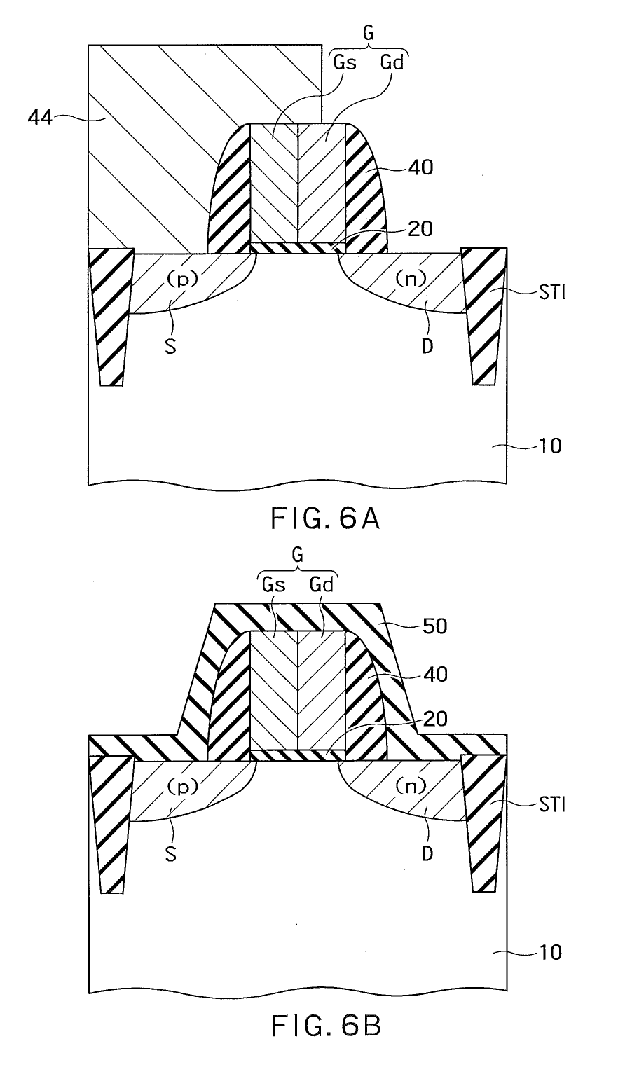

After the resist film 42 is removed, the source-layer-S formation region is covered by a resist film 44 by the lithographic technique as shown in FIG. 6A. Next, ions of an n-type impurity (for example, As) are implanted in the drain-layer-D formation region (the semiconductor layer 10 on the side of the second gate part Gd of the gate electrode G) by using the resist film 44 as a mask.

After the resist film 44 is removed, a stress inducing layer 50 is deposited on the gate electrode G and the semiconductor layer 10 by the CVD method as shown in FIG. 6B. For example, the stress inducing layer 50 is an insulation film such as a silicon nitride film. The stress inducing layer 50 is provided in order to apply a stress memorization technique that enables stress memorization by a method mentioned below to the first gate part Gs.

Next, a thermal process is performed to cause the first gate part Gs to memorize a stress due to the stress inducing layer 50. For example, the semiconductor layer 10 and the gate electrode G are thermally processed at a temperature of about 1050° C. by a spike annealing method. At this time, amorphous silicon of the first gate part Gs is altered into polysilicon. When amorphous silicon is altered into polysilicon, crystal grains of silicon grow while extending horizontally (in a channel length direction) because the top of the first gate part Gs is blocked by the stress inducing layer 50. As a result, the crystal grains of the first gate part Gs become polysilicon that extends horizontally (in the channel length direction) compared to crystal grains of the second gate part Gd. Because left and right sides of the first gate part Gs are also blocked by the sidewall film 40 and the second gate part Gd, respectively, strain due to the extension is applied to a bottom of the first gate part Gs.

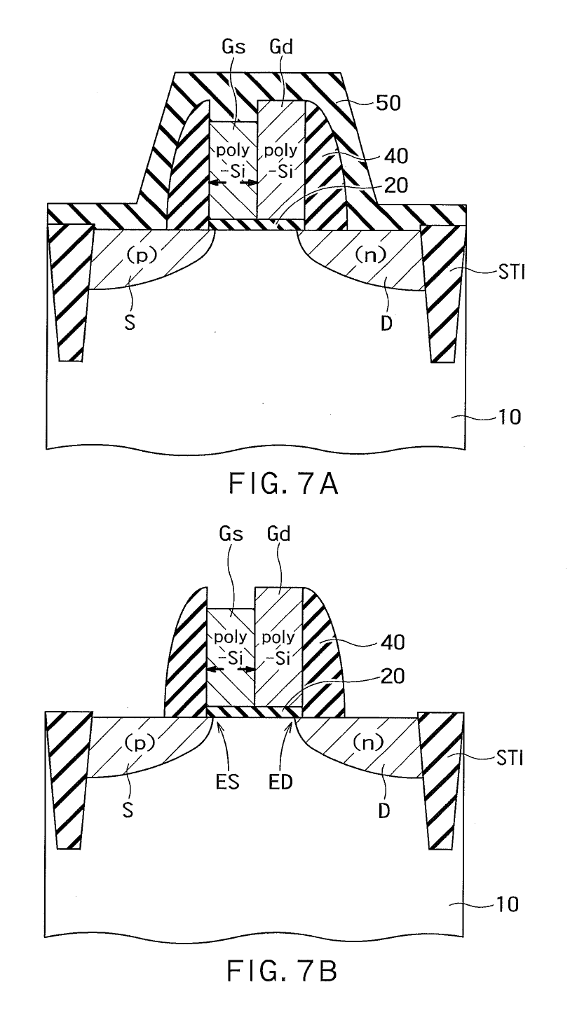

Because the first gate part Gs is altered into polysilicon having a horizontally-extending grain diameter, the first gate part Gs become lower as shown in FIG. 7A. Accordingly, the height of the first gate part Gs becomes lower than that of the second gate part Gd.

The thermal process for stress memorization also has a function of activating the impurities in the source layer S and the drain layer D. As a result, the source layer S is formed in the semiconductor layer 10 on the side of the first gate part Gs of the gate electrode G. The drain layer D is formed in the semiconductor layer 10 on the side of the second gate part Gd of the gate electrode G.

Next, the stress inducing layer 50 is removed. The first gate part Gs has been altered into polysilicon having the grain diameter that horizontally extends during the thermal process. For this reason, even when the stress inducing layer 50 is removed, the crystal grains of the first gate part Gs keep to extend horizontally (in the channel length direction). That is, the first gate part Gs memorizes a stress and continuously applies the stress to the source edge ES and the periphery thereof.

Thereafter, the interlayer dielectric film 60, contact plugs, and wires are formed, so that the TFET 100 is completed. According to the first embodiment, it is possible to cause the first gate part Gs to memorize a stress by using the stress inducing layer 50 and the thermal process. That is, with the stress memorization technique, the first gate part Gs itself can have a stress and apply the stress to the source edge ES.

The stress applied to the source layer S and the source edge ES can thus be set larger than that applied to the drain layer D and the drain edge ED. As a result, the TFET 100 can improve tunneling efficiency on the side of the source layer S that determines an on-state current without increasing tunneling efficiency on the side of the drain layer D that determines an off-state current.

The TFET 100 according to the first embodiment includes the gate electrode G made of polysilicon. However, the gate electrode G can be formed of a metal material. In this case, materials for the first and second gate parts Gs and Gd are selected to set the thermal expansion coefficient of the first gate part Gs larger than that of the second gate part Gd. Alternatively, the materials for the first and second gate parts Gs and Gd are selected to set the Young's modulus of the first gate part Gs smaller than that of the second gate part Gd. For example, combinations of the materials for the first gate part Gs and the second gate part Gd are as follows. That is, the material for the first gate part Gs is titanium nitride (TiN) and the material for the second gate part Gd is tungsten carbide (WC). Alternatively, the material for the first gate part Gs is tantalum carbide (TaC) and the material for the second gate part Gd is tungsten carbide (WC). These combinations satisfy the conditions of the thermal expansion coefficient or the Young's modulus mentioned above. Accordingly, even when the gate electrode G is formed of these metal materials, the stress applied to the source layer S and the source edge ES can be larger than that applied to the drain layer D and the drain edge ED, and effects of the first embodiment are not lost.

When the gate electrode G is formed of a metal material, it suffices that the metal material for the second gate part Gd is deposited in FIG. 2A and the metal material for the first gate part Gs is deposited in FIG. 3A. As a result, the TFET 100 that uses the metal materials mentioned above for the gate electrode G can be formed.

### Second Embodiment

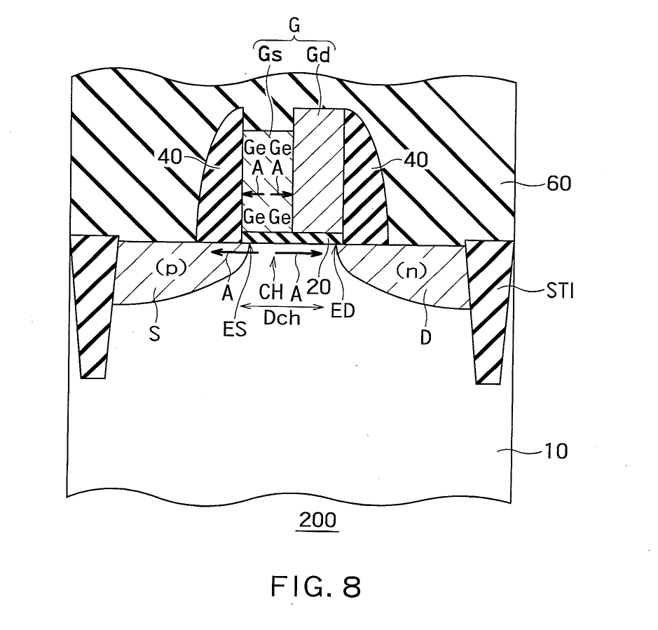

FIG. 8 is a cross-sectional view showing an example of a configuration of a TFET 200 according to a second embodiment. The second embodiment is different from the first embodiment in that the first gate part Gs contains an inert element having a larger atomic weight than that of silicon (for example, germanium (Ge)). Other configurations of the second embodiment can be identical to those of the first embodiment. Even when an inert element having a larger atomic weight than that of silicon is contained in the first gate part Gs, stress characteristics of the first gate part Gs and electrical characteristics of the TFET 200 are identical to those of the first embodiment. Therefore, the second embodiment can also achieve effects identical to those of the first embodiment.

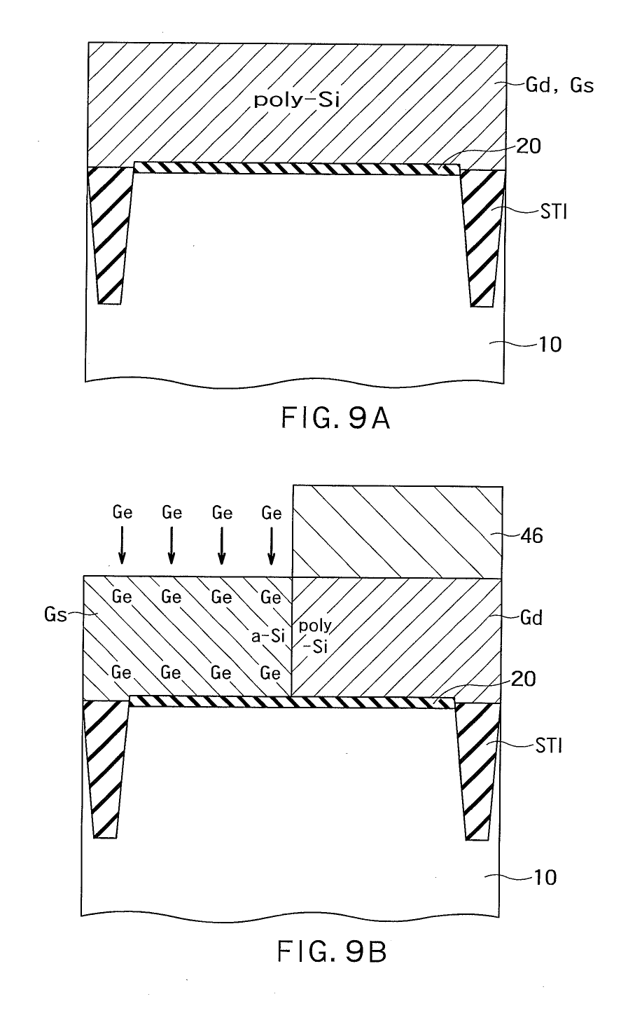

FIGS. 9A and 9B are cross-sectional views showing an example of a manufacturing method of the TFET 200 according to the second embodiment. As explained with reference to FIG. 2A, the shallow trench isolation regions STI are formed first in the semiconductor layer 10. Next, the gate dielectric film 20 is formed on the semiconductor layer 10.

Next, materials for the first gate part Gs and the second gate part Gd are deposited on a material for the gate dielectric film 20 by the CVD method. At first, the materials for the first gate part Gs and the second gate part Gd are, for example, polysilicon. Polysilicon is obtained by film formation of silicon in an atmosphere at a relatively high temperature of about 1000° C. by the CVD method. Next, an n-type impurity (for example, phosphorus) is implanted in the materials for the first and second gate parts Gs and Gd by, for example, the ion implantation method. As a result, the materials for the first and second gate parts Gs and Gd become conductive doped polysilicon. Consequently, a configuration shown in FIG. 9A is obtained.

Next, as shown in FIG. 9B, a region of the second gate part Gd is covered by a resist film 46 by the lithographic technique. Next, an inert element having a larger atomic weight than that of silicon is introduced in a region of polysilicon corresponding to the first gate part Gs. For example, germanium (Ge) is implanted in the region of the first gate part Gs. As a result, polysilicon in the region of the first gate part Gs is amorphized.

Next, polysilicon and amorphous silicon are processed by the lithographic technique and the etching technique. As a result, as shown in FIG. 4B, the first gate part Gs made of amorphous silicon and the second gate part Gd made of polysilicon are formed.

Processes explained with reference to FIGS. 4B to 7B are then performed, so that the TFET 200 shown in FIG. 8 is completed.

According to the manufacturing method of the second embodiment, polysilicon and amorphous silicon do not need to be deposited separately. As a result, according to the second embodiment, the first gate part Gs that has memorized a stress can be formed relatively easily. Furthermore, the second embodiment can also achieve effects identical to those of the first embodiment.

### Third Embodiment

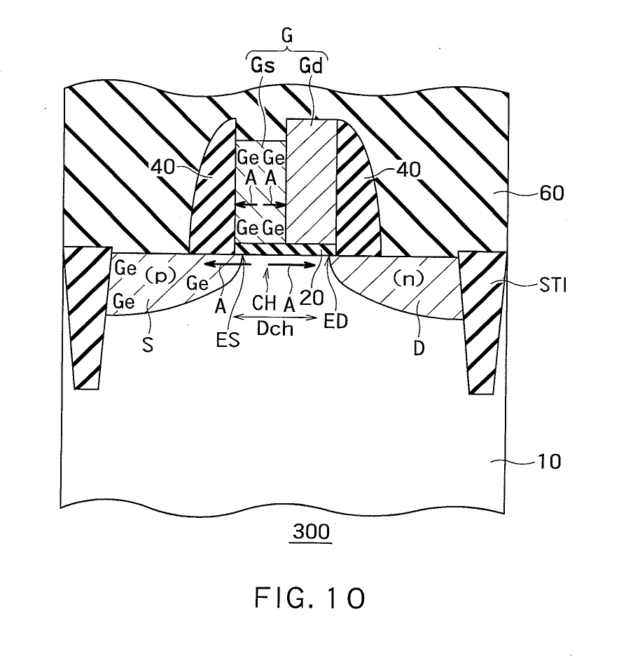

FIG. 10 is a cross-sectional view showing an example of a configuration of a TFET 300 according to a third embodiment. The third embodiment is different from the second embodiment in that the source layer S also contains an inert element having a larger atomic weight than that of silicon (for example, germanium (Ge)). By introducing an inert element having a larger atomic weight than that of silicon in the source layer S, the source layer S can be temporarily amorphized. Because the Young's modulus of amorphous silicon is smaller than that of crystalline silicon, an effect of applying strain by the stress memorization technique is enhanced. As a result, tunneling efficiency on the side of the source layer S can be further improved.

Other configurations of the third embodiment can be identical to those of the second embodiment. Stress characteristics of the first gate part Gs and other electrical characteristics of the TFET 300 can be identical to those of the second embodiment. Therefore, the third embodiment can also achieve effects identical to those of the second embodiment.

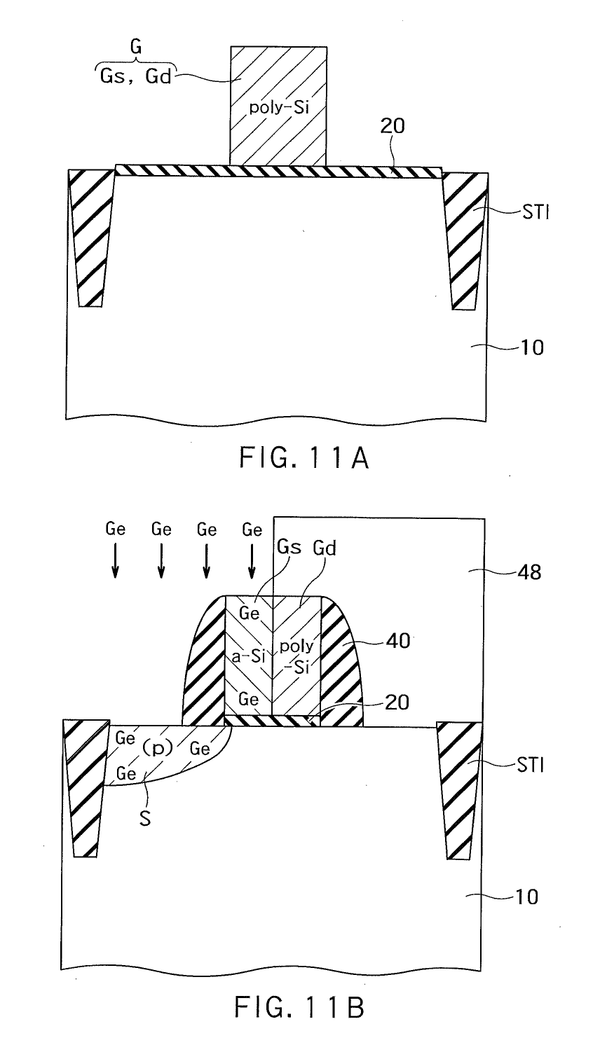

FIGS. 11A and 11B are cross-sectional views showing an example of a manufacturing method of the TFET 300 according to the third embodiment. As explained with reference to FIG. 2A, the shallow trench isolation regions STI are formed first in the semiconductor layer 10. Next, the gate dielectric film 20 is formed on the semiconductor layer 10. Next, as explained with reference to FIG. 9A, materials for the first gate part Gs and the second gate part Gd are formed on a material for the gate dielectric film 20. For example, the materials for the first gate part Gs and the second gate part Gd are doped polysilicon.

Next, as shown in FIG. 11A, the materials for the first gate part Gs and the second gate part Gd are processed in a pattern of the gate electrode G by the lithographic technique and the etching technique. At this stage, the materials for the first gate part Gs and the second gate part Gd are both formed of polysilicon.

Next, as explained with reference to FIG. 5A, the sidewall film 40 is formed on both side surfaces of the gate electrode G.

Next, as shown in FIG. 11B, a second-gate-part-Gd formation region (that is, a region where the second gate part Gd is formed) and the drain-layer-D formation region are covered by a resist film 48 by the lithographic technique. Next, a p-type impurity (for example, BF₂) is implanted in the source-layer-S formation region (the semiconductor layer 10) by using the resist film 48 shown in FIG. 11B as a mask.

Next, an inert element having a larger atomic weight than that of silicon is introduced in the first-gate-part-Gs formation region and the source-layer-S formation region by using the resist film 48 as a mask. For example, ions of germanium (Ge) are implanted in the first-gate-part-Gs formation region. As a result, polysilicon in a region of the first gate part Gs is amorphized. At the same time, ions of germanium (Ge) are implanted also in the source-layer-S formation region. As a result, the semiconductor layer 10 in the source-layer-S formation region is amorphized. Because not only the first gate part Gs but also the source-layer-S formation region is amorphized, a stress from the stress inducing layer 50 is easily introduced also in the source layer S as well as the first gate part Gs.

Processes explained with reference to FIGS. 6A to 7B are then performed, so that the TFET 300 shown in FIG. 10 is completed.

According to the manufacturing method of the third embodiment, not only the first gate part Gs but also the source layer S is amorphized. Because the Young's modulus of amorphous silicon is smaller than that of crystalline silicon, the effect of applying strain by the stress memorization technique is enhanced. Therefore, according to the third embodiment, it is possible to easily introduce a stress in not only the first gate part Gs but also the source layer S and cause the first gate part Gs and the source layer S to memorize the stress. Tunneling efficiency on the side of the source layer S can thus be further improved. In addition, by introducing germanium in the source layer S, a p-type impurity is hardly diffused and a concentration gradient of the source layer S becomes sharp. Furthermore, the third embodiment can also achieve effects identical to those of the second embodiment.

In the above embodiments, the N-TFETs 100 to 300 have been explained. However, it is needless to mention that the above embodiments can be applied to a P-TFET. In this case, the source layer S is an n-type diffusion layer and the drain layer D is a p-type diffusion layer.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor layer;
a first conductivity-type source layer in the semiconductor layer;
a second conductivity-type drain layer in the semiconductor layer;
a gate dielectric film on the semiconductor layer between the source layer and the drain layer; and
a gate electrode comprising a first gate part partially located on the gate dielectric film on a side of the source layer and a second gate part partially located on the gate dielectric film on a side of the drain layer, wherein
a length of crystal grains of the first gate part in a channel length direction is longer than that of crystal grains of the second gate part in the channel length direction.

2. The device of claim 1, wherein a thermal expansion coefficient of the first gate part is larger than that of the second gate part, or a Young's modulus of the first gate part is smaller than that of the second gate part.

3. The device of claim 1, wherein a height of the first gate part is lower than that of the second gate part.

4. The device of claim 1, wherein a material for the first gate part and a material for the second gate part are polysilicon.

5. The device of claim 4, wherein an inert element having a larger atomic weight than that of silicon is introduced in the first gate part.

6. The device of claim 4, wherein germanium is introduced in the first gate part.

7. The device of claim 4, wherein an inert element having a larger atomic weight than that of silicon is introduced in the first gate part and the source layer.

8. The device of claim 4, wherein germanium is introduced in the first gate part and the source layer.

9. The device of claim 1, further comprising:
a sidewall film on both side surfaces of the gate electrode, wherein
the sidewall film covers a side surface of the first gate part on a side of the source layer and a side surface of the second gate part on a side of the drain layer.

10. A semiconductor device comprising:
a semiconductor layer;
a first conductivity-type source layer in the semiconductor layer;
a second conductivity-type drain layer in the semiconductor layer;
a gate dielectric film on the semiconductor layer between the source layer and the drain layer; and
a gate electrode comprising a first gate part partially located on the gate dielectric film on a side of the source layer and a second gate part partially located on the gate dielectric film on a side of the drain layer, wherein
a thermal expansion coefficient of the first gate part is larger than that of the second gate part, or a Young's modulus of the first gate part is smaller than that of the second gate part.

11. The device of claim 10, wherein
a material of the first gate part is titanium nitride (TiN), and
a material of the second gate part is tungsten carbide (WC).

12. The device of claim 10, wherein
a material of the first gate part is tantalum carbide (TaC), and
a material of the second gate part is tungsten carbide (WC).

13. A manufacturing method of a semiconductor device, the method comprising:
forming a gate dielectric film on a semiconductor layer;
forming a first gate part and a second gate part that are made of different materials and adjacent to each other on the gate dielectric film as a gate electrode;
implanting a first conductivity-type impurity in the semiconductor layer on a side of the first gate part of the gate electrode and a second conductivity-type impurity in the semiconductor layer on a side of the second gate part of the gate electrode;
forming a layer that covers the gate electrode and induces strain; and
thermally processing the gate electrode covered by the layer.

14. The method of claim 13, wherein
the first gate part is formed of amorphous silicon and the second gate part is formed of polysilicon at a time of forming the gate electrode, and
the first gate part is altered from amorphous silicon into polysilicon at a time of thermally processing the gate electrode.

15. The method of claim 13, wherein
a material of the first gate part is formed of titanium nitride (TiN), and
a material of the second gate part is formed of tungsten carbide (WC).

16. The method of claim 13, wherein
a material of the first gate part is formed of tantalum carbide (TaC), and
a material of the second gate part is formed of tungsten carbide (WC).

17. The method of claim 13, wherein
formation of the gate electrode comprises:
forming a polysilicon layer on the gate dielectric film; and
introducing an inert element having a larger atomic weight than that of silicon in the first gate part of the polysilicon layer to alter the polysilicon layer of the first gate part into an amorphous silicon layer, and wherein
the first gate part is altered from amorphous silicon into polysilicon at a time of thermally processing the gate electrode.

18. The method of claim 17, wherein the inert element is germanium.

19. The method of claim 13, wherein
the semiconductor layer provided on a side of the first gate part of the gate electrode corresponds to a source-layer formation region in the semiconductor layer,
the semiconductor layer provided on a side of the second gate part of the gate electrode corresponds to a drain-layer formation region in the semiconductor layer, and
formation of the gate electrode comprises:
forming a polysilicon layer on the gate dielectric film;
processing the polysilicon layer in a pattern of the gate electrode; and
introducing an inert element having a larger atomic weight than that of silicon in the first gate part of the polysilicon layer together with the source-layer formation region of the semiconductor layer to alter the polysilicon layer of the first gate part into an amorphous silicon layer together with the source-layer formation region, and wherein
the first gate part and the source-layer formation region is altered from amorphous silicon into crystalline silicon at a time of thermally processing the gate electrode.

20. The method of claim 19, wherein the inert element is germanium.
